(19) United States
(12) Patent Application Publication
(10) Pub. No.: US 2012/0114870 A1
(43) Pub. Date: May 10, 2012

(54) MANUFACTURING METHOD OF NOBLE METAL PLATING LAYER

(75) Inventors: SUNG-YING TSAI, Taoyuan County (TW); MING-DER GER, Taoyuan County (TW); YUH SUNG, Taoyuan County (TW); YANN-CHENG CHEN, Taoyuan County (TW)

(73) Assignee: NATIONAL DEFENSE UNIVERSITY, Taoyuan County (TW)

(21) Appl. No.: 13/078,957

(22) Filed: Apr. 2, 2011

(30) Foreign Application Priority Data
Nov. 5, 2010 (TW) 099138223

(51) Int. Cl. C23C 14/18

(52) U.S. Cl. 427/528

(57) ABSTRACT

The invention discloses a manufacturing method of a noble metal plating layer comprising the following steps: preparing a base material which is an alloy including a nickel base and at least one element with high oxidation valence on an object to be plated; soaking the object to be plated in a plating solution including pre-plating noble metal ions to make the element in the base material to be dissolved in the plating solution to obtain at least one ion with high oxidation valence; performing a chemical displacement reaction among the base material, the at least one ion having high oxidation valence, and the pre-plating noble metal ion in the plating solution to precipitate the pre-plating noble metal ion onto a surface of the object to be plated to form a noble metal plating layer.

### BACKGROUND OF THE INVENTION

1. Field of the Invention

The present invention relates to a manufacturing method of a noble metal plating layer, and more particularly to a chemical displacement method for thickening a noble metal plating layer by the existence of ions having high oxidation valence.

2. Description of the Related Art

A noble metal plating layer made of gold, silver, platinum or palladium generally comes with physical properties with excellent electrical conductivity, malleability, and chemical stability, so that it is used extensively in many different areas including printed circuit board, semiconductor process, military weapon, chemical instrument, and decorative artwork. Electroplating is mainly used for gold technologies at an early stage. With the environmental protection and cost taken into consideration, the electroplating method is gradually replaced by a chemical plating method with the advantages of low cost, non-toxic process, simple and easy operation, and quick manufacturing process.

The chemical plating method can be divided into an electroless plating method and a chemical displacement method. The electroless plating method as disclosed in R.O.C. Pat. No. 1223011 adds hydrazine hydrate, hydroxylammonium salt or an organic antioxidant into a plating solution, such that gold ions are reduced and deposited onto an object to be plated. However, the gold metal in such method is precipitated by reacting the gold ions with the added reductant. The deposition thickness is limited by the chemical kinetics of the gold metal, so that the thickness is only 2.3 micro-inches to 10.3 micro-inches (equivalent to 0.025 μm to 0.25 μm). In R.O.C. Pat. No. 1262218, a complexant and polyethyleneimine are added, such that metal ions in an electroplating bath are autocatalytic and stable to produce a gold deposition with a thickness of 1.57 μm in 50 minutes. Although the effect of the electroless plating method used for forming a gold plating layer is not bad, the plating solution of the electroless plating method has a complicated composition, and the added organic compounds are restricted and affected by the sequence, concentration, and impurity, and the preparation and usage are difficult to maintain. As a result, its applications are limited in practice.

In the chemical displacement method, a metal with a relatively lower standard reduction potential is used as a sacrificial metal, so that metal ions with a relatively higher standard reduction potential are displaced in the plating solution and reduced on a surface of the sacrificial metal to achieve the effect of plating a metal in the plating solution. The main driving force of the chemical displacement method is the oxidation reduction potential difference between two metal reactants that causes an electron transfer between two metal reactants. The metal with a lower standard reduction potential in a plating solution transfers electrons to the metal ions with a higher standard reduction potential, such that the metal ions in the plating solution can obtain electrons to form a metal layer. The redox reaction can be represented by the following chemical reaction equation:

Z₂M₁^{+Z}^{ᵢ}+Z₁M₂→Z₁M₂^{+Z}^{₂}+Z₂M₁

In conventional chemical displacement methods used for displacing a gold metal, a displacement reaction is performed by a nickel base material and gold ions to plate gold on the nickel base material, such as disclosed in “Gold Immersion Deposition on Electroless Nickel Substrates Deposition Process and Influence Factor Analysis” of J. of Electrochemical Society, 154(12), 2007 by Haiping Liu et. al. It discloses a method of using a nickel base material to displace gold, and the displacement speed is 0.0678 μm per 10 minutes. But the displacement reaction in this method is limited to a redox reaction between the gold ions in a plating solution and the nickel base material, such that when the surface of the nickel base material is covered by a gold metal plating layer reduced from its ion in the plating solution, the redox reaction between the nickel base material and the gold ions in the plating solution will be terminated. In other words, the plating layer will not continue growing, and the gold metal plating layer has a limited thickness. Since the thickness of the gold metal plating layer cannot be increased, the application of the gold metal plating layer will be limited.

In similar technologies as disclosed in R.O.C. Pat. Nos. 1305240 and 546408, the thickness of gold displaced by the chemical displacement method is from 0.047 μm to 0.1 μm.

For special printed circuit board, semiconductor process, military weapon or chemical instrument, the required thickness of displaced gold of the object to be plated must be 1.25 μm (0.5 micro-inch) or above. To increase the thickness of the displaced gold, “Electroless gold plating from a hypophosphite-dicyanoaurate bath”, Surface and Coating Technology 176, 2004 disclosed by T. N. Vorobyova, et al adds a reductant such as hypophosphite-dicyanoaurate in the plating solution, so that the thickness of gold is displaced by 0.3 μm/10 minutes. Although the addition of the reductant can increase the thickness of the metal plating layer, it also complicates the composition of the plating solution and causes a difficult maintenance and an increased cost of the plating solution.

Therefore, it is an important subject for the related industry to find a chemical displacement method of displacing a noble metal by providing a material with a reduction function to replace a conventional reductant such as hypophosphite-dicyanoaurate, potassium borohydride, sodium borohydride, sodium hypophosphite, hydrazine, and tetraethyl pentylamine, such that the plating solution does not have the problems of a complicated composition and a difficult maintenance of the plating solution due to the existence of the traditional reductant, and it is capable of achieving the requirement of the thickness of the displaced gold on the object to be plated over 1.25 μm.

### SUMMARY OF THE INVENTION

Therefore, it is a primary objective of the present invention to overcome the aforementioned shortcomings of the prior art by providing a manufacturing method of a noble metal plating layer to achieve the effects of having a simple maintenance of the displaced plating solution, increasing and controlling the thickness of the noble metal plating layer.

To achieve the foregoing objective, the present invention provides a manufacturing method of a noble metal plating layer comprising the following steps. A base material is formed on a pre-processed object to be plated, wherein the base material is an alloy including a nickel base and at least one element having high oxidation valence. The object to be plated is soaked in a plating solution with a pre-plating noble metal ion, such that at least one element having high oxidation valence of the base material is dissolved in the plating solution to form at least one ion having high oxidation valence. The pre-plating noble metal ion is precipitated on a surface of the plated object to form a noble metal plating layer by a chemical displacement reaction in the plating solution among the base material, the at least one ion having high oxidation valence, and the pre-plating noble metal ion.

To achieve the foregoing objective, the present invention provides another manufacturing method of a noble metal plating layer comprising the following steps. A base material is formed on a pre-processed object to be plated, in which the base material includes a nickel base. The object to be plated is soaked in a plating solution including a pre-plating noble metal ion and at least one ion having high oxidation valence. The pre-plating noble metal ion is precipitated on a surface of the plated object to form a noble metal plating layer by a chemical displacement reaction in the plating solution among the base material, at least one ion having high oxidation valence, and the pre-plating noble metal ion.

Wherein, at least one ion having high oxidation valence has a standard reduction potential lower than that of the pre-plating noble metal ion.

As stated above, the manufacturing method of a noble metal plating layer of the present invention has one or more of the following advantages:

(1) The ion of the present invention has a standard reduction potential lower than that of the pre-plating noble metal ion and can be oxidized to an ion with high oxidation valence, such that the effect of increasing the thickness of the noble metal plating layer can be achieved by using a simple plating solution in a chemical displacement method. Compared with a conventional electroless plating method, the present invention has the advantages of a simple plating solution, an easy maintenance, and a low cost.

(2) The composition of ions having high oxidation valence in the plating solution is adjusted in the chemical displacement method for controlling the speed and thickness of the precipitation during the displacement of the noble metal plating layer. In addition, the reaction time is controlled in the chemical displacement method to control the thickness of the metal plating layer.

(3) The porosity of the noble metal plating layer is reduced to provide the advantages of excellent coatability and integrity of the noble metal plating layer to improve the reliability of plated products and reduce the variance of the production.

### BRIEF DESCRIPTION OF THE DRAWINGS

FIG. 1 is a flow chart of a first manufacturing method of a noble metal plating layer in accordance with the present invention;

FIG. 2 is a flow chart of a second manufacturing method of a noble metal plating layer in accordance with the present invention;

FIG. 3 is a cross-sectional view of a displaced gold plating layer in accordance with a comparative example;

FIG. 4 is a cross-sectional view of a displaced gold plating layer in accordance with a first embodiment of the present invention;

FIG. 5 is a cross-sectional view of a displaced gold plating layer in accordance with a second embodiment of the present invention;

FIG. 6 is a graph of potential versus current density obtained from an electrochemical corrosion test;

FIG. 7 is a cross-sectional view of a displaced gold plating layer formed within a reaction time of 0.5 minute in accordance with a third embodiment of the present invention;

FIG. 8 is a cross-sectional view of a displaced gold plating layer formed within a reaction time of one minute in accordance with the third embodiment of the present invention;

FIG. 9 is a cross-sectional view of a displaced gold plating layer formed within a reaction time of 30 minutes in accordance with the third embodiment of the present invention;

FIG. 10 is a cross-sectional view of a displaced gold plating layer formed within a reaction time of 60 minutes in accordance with the third embodiment of the present invention;

FIG. 11 is a schematic view of the displaced gold plating layer in accordance with the second embodiment viewed under a high-amplification electronic microscope; and

FIG. 12 is a cross-sectional view of a displaced gold plating layer in accordance with a fourth embodiment of the present invention.

### DETAILED DESCRIPTION OF THE PREFERRED EMBODIMENTS

The foregoing and other objectives, characteristics and advantages of the present invention will become apparent by the detailed description of a preferred embodiment as follows. It is noteworthy to point out that each preferred embodiment is provided for the purpose of illustrating the present invention only, but not intended for limiting the scope of the present invention.

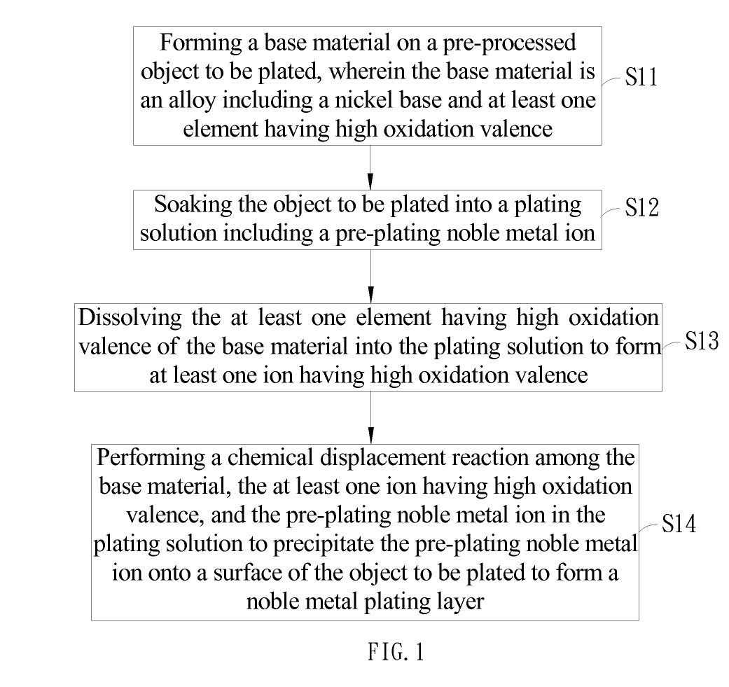

With reference to FIG. 1 for a flow chart of a first manufacturing method of a noble metal plating layer in accordance with the present invention, the method comprises the following steps. Step (S11): a base material is formed on a pre-processed object to be plated, wherein the base material is an alloy including a nickel base and at least one element having high oxidation valence. Step (S12): the object to be plated is soaked in a plating solution with a pre-plating noble metal ion. Step (S13): at least one ion having high oxidation valence is formed by dissolving at least one element having high oxidation valence of the base material in a plating solution. Step (S14): The pre-plating noble metal ion is precipitated on a surface of the plated object to form a noble metal plating layer by a chemical displacement reaction in the plating solution among the base material, the at least one ion having high oxidation valence, and the pre-plating noble metal ion.

In the first method, an alloy including at least one element having high oxidation valence and a nickel base is used as a base material for displacing a surface of the object to be plated in a chemical displacement method. The one ion having high oxidation valence will be dissociated from the element having high oxidation valence in the base material on the surface of the object to be plated in the plating solution. Meanwhile, the at least one ion having high oxidation valence can be oxidized to a high oxidation valence such as +2 valence to +5 valence or even higher oxidation valence, and has a standard reduction potential lower than that of the pre-plating noble metal ion. Therefore, the base material can be an alloy including a nickel base and at least one element having high oxidation valence such as nickel-molybdenum, nickel-manganese, nickel-cobalt, nickel-cobalt-molybdenum, nickel-cobalt-manganese, nickel-molybdenum-manganese, and the at least one element having high oxidation valence in the base material can be decomposed into the ion with a standard reduction potential lower than the pre-plating noble metal ion. Therefore, the ion can be oxidized to become an ion with a high oxidation valence.

When the surface of the object to be plated having the base material is soaked into the plating solution for a chemical displacement reaction, the at least one element having high oxidation valence will be decomposed from the base material to form at least one ion having high oxidation valence, such that a redox reaction is initiated among the at least one ion having high oxidation valence, the base material and the pre-plating noble metal ion. Therefore, after the pre-plating metal is precipitated fully on the surface of the base material of the object to be plated, the chemical displacement reaction will still continue such that a noble metal plating layer with a thickness greater than that produced in the conventional displacement method can be obtained. The pre-plating noble metal ion can be a noble metal ion of gold, silver, palladium or platinum and is generally produced by adding metal salts corresponding to such ions into the plating solution. The at least one element having high oxidation valence can be an element such as molybdenum (Mo), cobalt, manganese, rhenium or columbium which can be oxidized to ions with a high oxidation valence such as a valence of +2, +3, +4, +5 or above, and the produced ion has a standard reduction potential lower than that of the pre-plating metal ion. In the chemical displacement process, the at least one ion having high oxidation valence is oxidized from a low valence to a high valence, and the pre-plating noble metal ion in the plating solution receives electrons to be reduced and deposited on a surface of the base material of the object to be plated to form a noble metal plating layer. Therefore, when the at least one element having high oxidation valence in the base material is dissolved into the plating solution, the ions having high oxidation valence produced in the chemical displacement process plays the role of a reductant.

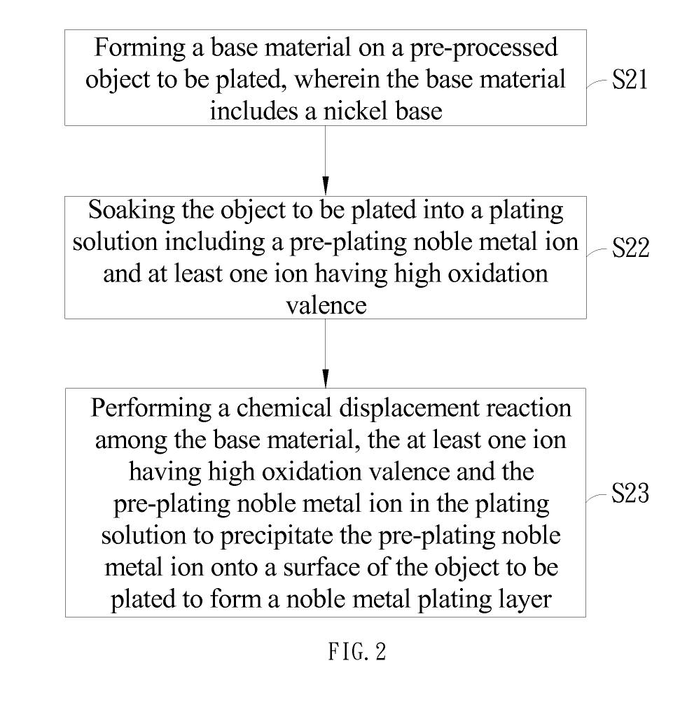

With reference to FIG. 2 for a flow chart of a second manufacturing method of a noble metal plating layer in accordance with the present invention, the method comprises the following steps. Step (S21): a base material is formed on a pre-processed object to be plated, wherein the base material includes a nickel base. Step (S22): the object to be plated is soaked into a plating solution including a pre-plating noble metal ion and at least one ion having high oxidation valence. Step (S23): a chemical displacement reaction among the base material, the at least one ion having high oxidation valence, and the pre-plating noble metal ion is performed in the plating solution to precipitate a pre-plating noble metal ion on a surface of the object to be plated to form a noble metal plating layer.

The main difference between the second method and the first method resides on that the second method provides ions having high oxidation valence and a standard reduction potential lower than that of the pre-plating noble metal ion directly into the plating solution. In addition, an element with a high valence number or its salt is added into the plating solution to dissolve and produce at least one ion having high oxidation valence. The at least one ion having high oxidation valence can be ion of molybdenum (Mo), cobalt, manganese, rhenium or columbium which can be oxidized to a high oxidation valence such as a valence of +2, +3, +4, +5 or above. In the chemical displacement process, the at least one ion having high oxidation valence is oxidized from a low valence to a high valence, and the pre-plating noble metal ion will receive electrons to be reduced and deposited on a surface of the base material of the object to be plated to form a noble metal plating layer. The pre-plating noble metal ion can be a noble metal ion gold, silver, palladium or platinum, and the pre-plating noble metal ion is generally produced by adding a salt of the noble metal into the plating solution.

In these two methods, the object to be plated can be metal, ceramic, glass or plastic. Moreover, because there is a protective layer made of a polymer compound such as green paint or resin on the surface of the object to be plated which causes an anti-corrosion effect, the object to be plated is pre-processed to modify and activate the surface of the object to be plated, such that the surface of the object to be plated is suitable for the reaction of forming a base material of an alloy.

In the pre-processing step, the surface of the object to be plated is rinsed by water first, and then an alkaline rinse takes place. Any alkaline solution remained on the surface of the object to be plated is removed by clean water after the alkaline rinsing process, and then an acid rinse takes place to modify the surface. Any acidic solution remained on the surface of the object to be plated is removed by clean water. A step of determining whether or not to perform a pre-soaking process according to the quality of the plated object takes place, and finally an activation step is carried out to facilitate the preparation of a base material of an alloy. The water used for the pre-processing process can be underground water, tap water or recycled water, and the solution used for the alkaline rinse can be an alkaline solution containing sodium hydroxide, and the solution used for the acidic rinse can be an acidic solution such as sulfuric acid, nitric acid or hydrochloric acid, and the activating solution used for the activation step can be a solution containing palladium, nickel or tin or their mixed solution.

Since there are different ways of synthesizing the nickel base in the base material, the nickel base in said two methods not only includes nickel but may also include other products produced by the reaction of forming the nickel base. If the electroless plating method is used for producing the nickel base, a small quantity of phosphorus will exist in the nickel base. In addition to the electroless plating method, the alloy base material can be prepared by fusing, sputtering, evaporating or electroplating an alloy. After the alloy base material is prepared, clean water is used for rinsing its surface, and then the chemical displacement reaction takes place. In the first and second methods, after the chemical reaction is completed, the object to be plated is removed and its displaced noble metal plating layer is rinsed by clean water, and finally placed and dried by an oven to complete preparing the noble metal plating layer.

The following embodiments of the present invention and a comparative example are used for describing the present invention, but the scope of the present invention is not limited by these preferred embodiments and the comparative example. In the following embodiments and the comparative example, the displaced gold is used as an example for the illustration, and other noble metals such as silver, platinum or palladium can be used by changing the pre-plating noble metal ion and conductive salt in the plating solution and its corresponding chelating agent of the pre-plating noble metal ion.

### COMPARATIVE EXAMPLE

The composition of the nickel-phosphorus alloy is nickel:phosphorus=92:8

| Gold potassium cyanide | 3 | g/L |
|---|---|---|
| Ammonium chloride | 30 | g/L |
| Sodium citrate | 30 | g/L |
| pH | 6.5 | |
| Plating solution temperature | 88° | C. |
| Reaction time | 60 | minutes |

### First Embodiment

The composition of a nickel-molybdenum-phosphorus alloy is nickel:molybdenum:phosphorus=88:4:8

| Gold potassium cyanide | 3 | g/L |
|---|---|---|
| Ammonium chloride | 30 | g/L |
| Sodium citrate | 30 | g/L |
| pH | 6.5 | |
| Plating solution temperature | 88° | C. |
| Reaction time | 60 | minutes |

### Second Embodiment

The composition of a nickel-molybdenum-phosphorus alloy is nickel:molybdenum:phosphorus=83:7:9

| Gold potassium cyanide | 3 | g/L |
|---|---|---|
| Ammonium chloride | 30 | g/L |
| Sodium citrate | 30 | g/L |
| pH | 6.5 | |
| Plating solution temperature | 88° | C. |
| Reaction time | 60 | minutes |

### Third Embodiment

The composition of a nickel-molybdenum-phosphorus alloy is nickel:molybdenum:phosphorus=83:7:9

| Gold potassium cyanide | 3 | g/L |
|---|---|---|
| Ammonium chloride | 30 | g/L |
| Sodium citrate | 30 | g/L |
| pH | 6.5 | |
| Plating solution temperature | 88° | C. |

| | |
|---|---|
| Reaction time | 0.5 minute, 1 minute, 30 minutes, |
| | and 60 minutes |

### Fourth Embodiment

The composition of a nickel-phosphorus alloy is nickel:phosphorus=92:8

| Gold potassium cyanide | 3 | g/L |
|---|---|---|
| Ammonium chloride | 30 | g/L |
| Sodium citrate | 30 | g/L |
| Manganese sulfate | 1 | g/L |
| pH | 6.5 | |
| Plating solution temperature | 88° | C. |
| Reaction time | 60 | minutes |

Each of the aforementioned embodiments and the comparative example uses a chemical displacement method to displace a nickel base alloy layer to form a gold plating layer. Since the nickel base of the base material is prepared by the electroless plating method, the nickel base contains the element phosphorus. Each embodiment and the comparative example are controlled in the same environment for the reaction, such that they can be compared as follows.

The comparative example does not include any element with high valence number, and the chemical displacement method is adopted for displacing the nickel base alloy layer to form the gold plating layer. In the comparative example, the atomic percentage (at %) of each element in the alloy base material is nickel:phosphorus=92:8(at %), and this comparative example is used as a control group for each embodiment of the present invention for studying the effect of synthesizing the element with high oxidation valence in the base material to decompose ions having high oxidation valence or directly adding ions with high oxidation valence into the plating solution in accordance with the present invention on the thickness of the gold plating layer.

The comparative example, first embodiment and second embodiment are used for studying the effect of different compositions of elements with high oxidation valence in an alloy on the thickness of the gold plating layer. In the comparative example, the atomic percentage (at %) of each element in the alloy base material is nickel:phosphorus=92:8 (at %). In the first embodiment, the atomic percentage (at %) of each element in the alloy base material is nickel:molybdenum:phosphorus=88:4:8 (at %). In the second embodiment, the atomic percentage (at %) of each element in the alloy base material is nickel:molybdenum:phosphorus=83:7:9 (at %). The error tolerance of the atomic percentage of elements in each alloy is preferable less than 3%.

As shown above, the comparative example and each embodiment adopt the same environment for the plating solution, and each plating solution includes gold potassium cyanide 3 g/L, ammonium chloride 30 g/L, sodium citrate 30 g/L, and the same pH value of 6.5 and temperature of 88° C., and the reaction time is controlled at 60 minutes. A gold salt such as gold sodium sulfite or gold potassium cyanide is dissolved in the plating solution to provide gold ions. In the comparative example and each embodiment, gold potassium cyanide is dissolved in the plating solution to provide gold ions. In addition, sodium citrate is used as a chelating agent and provides citrate for stabilizing the gold ions, such that it prevents the gold ions from becoming hydroxide in the water solution with a higher pH value; and ammonium chloride (NH₄Cl) is used as a conductive salt and provided for improving the electrical conductivity of the plating solution while changing the surface diffusion layer structure of the substrate of the object to be plated.

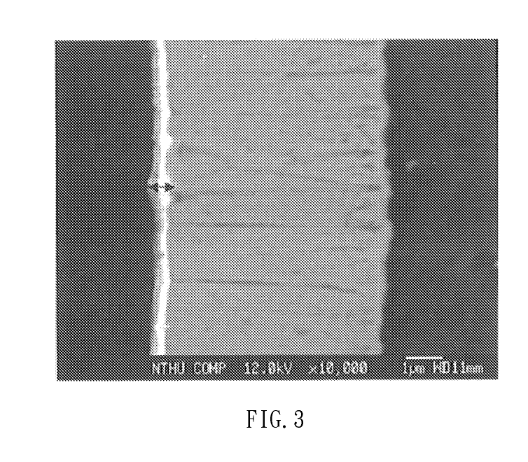

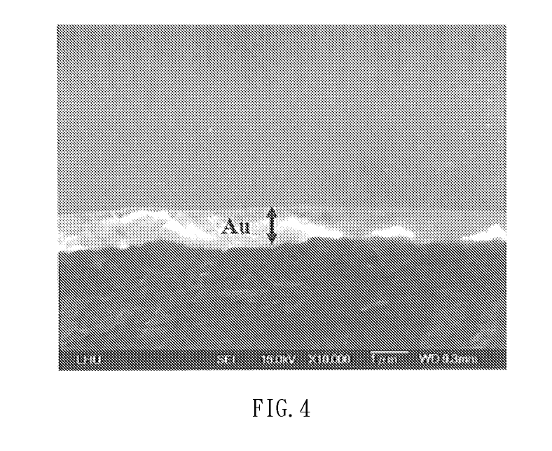

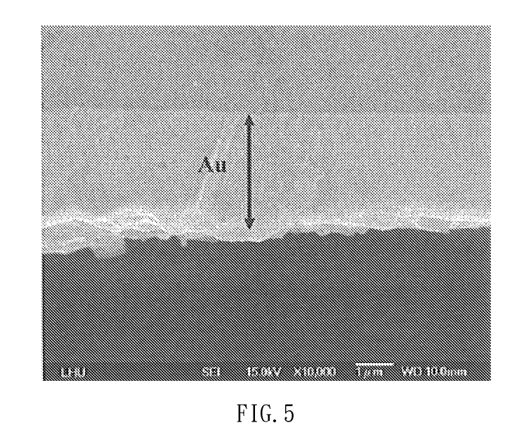

The comparison of the experiment results is given for displacing gold plating layers as shown in FIG. 3 to FIG. 5 by different alloy proportions. FIG. 3, FIG. 4, and FIG. 5 are cross-sectional views of a displaced gold plating layer in accordance with the comparative example, the first embodiment of the present invention, and the second embodiment of the present invention, respectively.

The cross-sectional view of the gold plating layers formed by the comparative example and observed under an electronic microscope shows that the thickness of the gold plating layer obtained by simply using a nickel-phosphorus alloy without containing any element of high valence number is 0.15 μm. In the first embodiment, if the alloy base material includes the element molybdenum that can be oxidized to high oxidation valence, and the proportion of nickel:molybdenum:phosphorus is 88:4:8 (at %), the thickness of the displaced gold plating layer is increased to 0.7 μm. In the second embodiment, if the content of the molybdenum is increased in the proportion of the alloy to nickel:molybdenum:phosphorus=83:7:9 (at %), the thickness of the displaced gold plating layer can reach up to 2.1 μm.

This comparison shows that the present invention can increase the thickness of the displaced gold plating layer by using an alloy base material including nickel base and at least one element with a standard reduction potential lower than that of a pre-plating noble metal ion and a high valence number for displacing the plating layer on the surface of the object to be plated. Moreover, the content of alloy base material in the at least one element having high oxidation valence can be increased to further improve the effects of thickening the gold plating layer. In other words, the proportion of the elements with high valence number can be adjusted to achieve the effect of controlling the thickness of the noble metal plating layer.

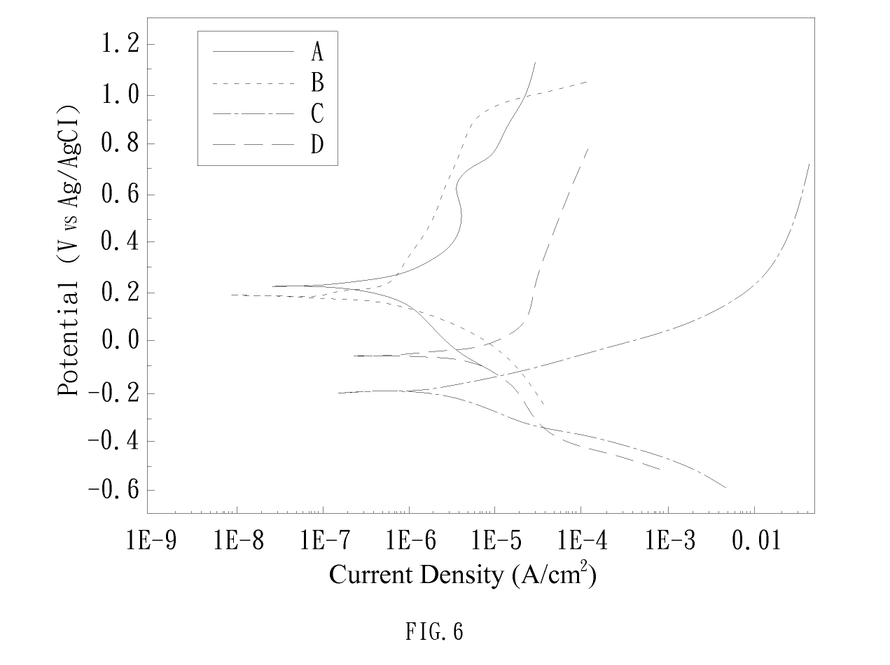

An electrochemical test is used for demonstrating the difference of the electrochemical property between the displaced gold plating layer obtained in the present invention and pure gold. With reference to FIG. 6 for a graph of potential versus current density obtained from an electrochemical corrosion test, line A indicates the electrochemical property of pure gold: line B indicates the electrochemical property of the displaced gold plating layer with a thickness of 0.7 μm formed according to the embodiment of the present invention; line C indicates the electrochemical property of the displaced gold plating layer of the comparative example, and its thickness is 0.15 μm, and line D indicates the electrochemical property of a nickel base alloy. According to the result of the electrochemical corrosion test, the displaced gold plating layer of the present invention with a thickness of 0.7 μm has the similar surface potential and similar corrosion resistance as those of the pure gold.

In the third embodiment; a constant proportion of an alloy base material, at least one element having high oxidation valence and other elements is adopted, and the effect of the reaction time on the thickness of the gold plating layer is studied. In this embodiment, the proportion of each element in the alloy base material is the same as that of the second embodiment, and the composition, pH value, and temperature of the plating solution are the same as those of the second embodiment, except the reaction time is changed to 0.5 minute, 1 minute, 30 minutes and 60 minutes for studying the effect of the reaction time on the displaced gold plating layer.

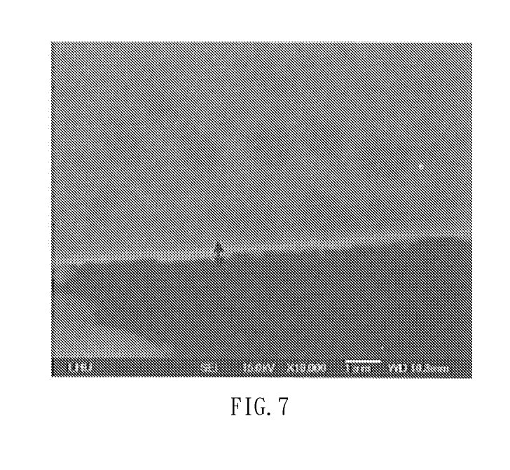

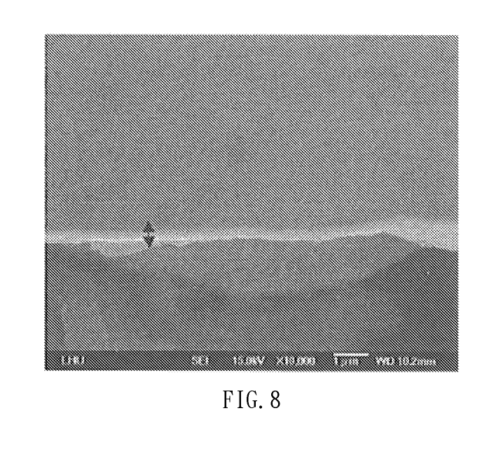

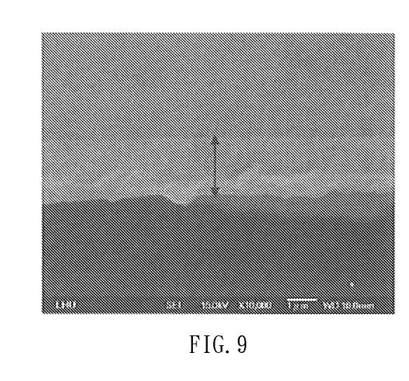

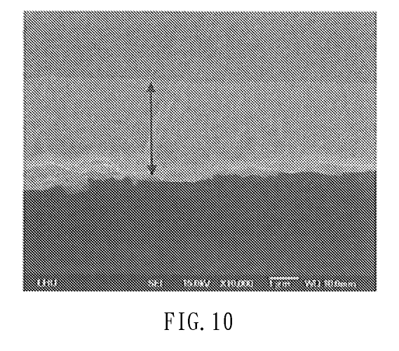

With reference to FIGS. 7 to 10, they are the cross-sectional views of different displaced gold plating layers produced in different reaction times in accordance with the third embodiment of the present invention. FIG. 7 shows the cross-sectional view of a gold plating layer produced within a reaction time of 0.5 minute. FIG. 8 shows the cross-sectional view of a gold plating layer produced within a reaction time of 1 minute. FIG. 9 shows the cross-sectional view of a gold plating layer produced within a reaction time of 30 minutes. FIG. 10 shows the cross-sectional view of a gold plating layer produced within a reaction time of 60 minutes. Each cross-sectional view of the gold plating layer produced with a different reaction time in the third embodiment is observed under an electronic microscope, and the results show that the thickness of the gold plating layer is increased with the reaction time. In other words, when the content of the element with a high valence number in the alloy base material is constant, the manufacturing method of a noble metal plating layer of the present invention can control the thickness of the noble metal plating layer by adjusting the reaction time.

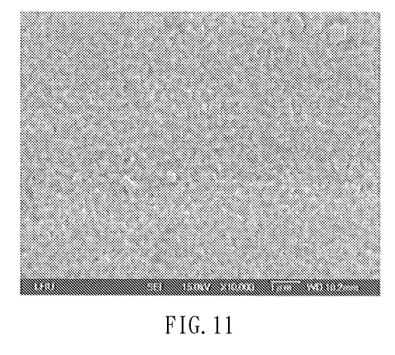

With reference to FIG. 11 for a schematic view of an observation of a displacement in accordance with the second embodiment, which is viewed under a high-amplification electronic microscope, the displaced gold plating layer has no pores, so it is a gold plating layer with excellent coatability and integrity. Therefore, the manufacturing method of a noble metal plating layer of the present invention has the advantages of improving the reliability of the plated object and reducing the variance of the production.

Comparing the comparative example and the fourth embodiment, the effect of the displaced gold plating layer is studied, wherein the ions having high oxidation valence are added into the plating solution directly, instead of decomposing the element having high oxidation valence from the base material into the plating solution to produce ions with high oxidation valence. The alloy base material used in both of the fourth embodiment and the comparative example is the same, in which the proportion of each element in the alloy is nickel:phosphorus=92:8 (at %), and each reaction condition of this fourth embodiment is the same as the comparative example, except that manganese sulfate is added into the plating solution of the fourth embodiment, in which the content of manganese sulfate in the plating solution is 1 g/L, such that manganese ions are decomposed from the plating solution in the fourth embodiment and provided for the chemical displacement reaction.

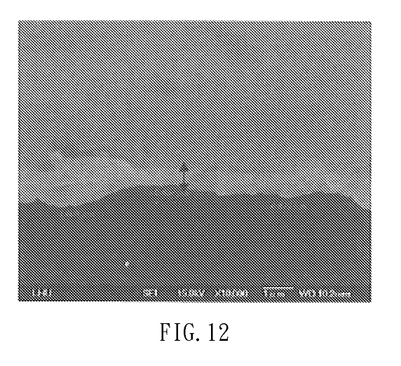

With reference to FIG. 12 for a cross-sectional view of displacing a gold plating layer in accordance with the fourth embodiment of the present invention, the result shows that the thickness of the gold plating layer can be increased significantly, if there is at least one ion with a standard reduction potential lower than that of the pre-plating noble metal ion and a high oxidation valence in the plating solution. As shown in FIG. 12, the gold plating layer obtained with the existence of manganese ions is much thicker than the gold plating layer with thickness of 0.15 μm obtained without the existence of the manganese ions.

The cross-sectional view of the gold plating layer formed in the fourth embodiment and observed by an electronic microscope shows that the addition of manganese ions in the plating solution can increase the thickness of the displaced gold plating layer. In other words, the manufacturing method of a noble metal plating layer of the present invention can supply ions having high oxidation valence directly into the plating solution of the chemical displacement method to achieve the effect of thickening the displaced noble metal plating layer.

What is claimed is:

1. A manufacturing method of a noble metal plating layer, comprising the steps of:
forming a base material on a pre-processed object to be plated, wherein the base material is an alloy including a nickel base and at least one element having high oxidation valence;
soaking the object to be plated into a plating solution including a pre-plating noble metal ion;
dissolving the at least one element having high oxidation valence of the base material into the plating solution to form at least one ion having high oxidation valence; and
performing a chemical displacement reaction among the base material, the at least one ion having high oxidation valence, and the pre-plating noble metal ion in the plating solution to precipitate the pre-plating noble metal ion onto a surface of the object to be plated to form a noble metal plating layer.

2. The manufacturing method of a noble metal plating layer as recited in claim 1, wherein the at least one ion having high oxidation valence has a standard reduction potential lower than that of the pre-plating noble metal ion.

3. The manufacturing method of a noble metal plating layer as recited in claim 1, wherein when the plating solution includes gold potassium cyanide, the pre-plating noble metal ion is a gold ion and the noble metal plating layer is a gold plating layer.

4. The manufacturing method of a noble metal plating layer as recited in claim 3, wherein the at least one element with high oxidation valence includes molybdenum.

5. The manufacturing method of a noble metal plating layer as recited in claim 4, wherein when the base material is produced by an electroless plating method, the base material further includes phosphorus.

6. The manufacturing method of a noble metal plating layer as recited in claim 5, wherein the base material is a nickel-molybdenum-phosphorus alloy, and the atomic percentage (at %) for nickel, molybdenum and phosphorus is nickel:molybdenum:phosphorus=88:4:8 (at %) or nickel:molybdenum:phosphorus=83:7:9 (at %), and the error tolerance of the atomic percentage of nickel, molybdenum and phosphorus is 3%.

7. The manufacturing method of a noble metal plating layer as recited in claim 1, wherein the thickness of the noble metal plating layer is controlled by controlling the reaction time of the base material in the plating solution, or controlling the composition proportion of the at least one element with high oxidation valence in the base material.

8. A manufacturing method of a noble metal plating layer comprising the steps of:
forming a base material on a pre-processed object to be plated, wherein the base material includes a nickel base;
soaking the object to be plated into a plating solution including a pre-plating noble metal ion and at least one ion having high oxidation valence; and
performing a chemical displacement reaction among the base material, the at least one ion having high oxidation valence and the pre-plating noble metal ion in the plating solution to precipitate the pre-plating noble metal ion onto a surface of the object to be plated to form a noble metal plating layer.

9. The manufacturing method of a noble metal plating layer as recited in claim 8, wherein the at least one ion having high oxidation valence has a standard reduction potential lower than that of the pre-plating noble metal ion.

10. The manufacturing method of a noble metal plating layer as recited in claim 8, wherein the at least one ion having high oxidation valence is produced by dissolving a salt belonging to at least one element having high oxidation valence into the plating solution.

11. The manufacturing method of a noble metal plating layer as recited in claim 8, wherein when the plating solution includes gold potassium cyanide, the pre-plating noble metal ion is a gold ion, and the noble metal plating layer is a gold plating layer.

12. The manufacturing method of a noble metal plating layer as recited in claim 11, wherein when the base material is produced by an electroless plating method, the base material is a nickel-phosphorus alloy, and the atomic percentage (at %) for nickel and phosphorus is nickel:phosphorus=92:8 (at %), and the error tolerance of the atomic percentage of nickel and phosphorus is 3%.

13. The manufacturing method of a noble metal plating layer as recited in claim 12, wherein the at least one ion with high oxidation valence is a manganese ion, and the manganese ion is produced by dissolving manganese sulfate into the plating solution.

14. The manufacturing method of a noble metal plating layer as recited in claim 13, wherein the thickness of the noble metal plating layer is controlled by controlling the reaction time of the base material in the plating solution, or controlling the composition proportion of the manganese ion in the plating solution.
